(19) United States
(12) Patent Application Publication
(10) Pub. No.: US 2025/0182799 A1
(43) Pub. Date: Jun. 5, 2025

(54) HARD DISK CONTROL SYSTEM AND METHOD, AND RELATED COMPONENT

(71) Applicant: SUZHOU METABRAIN INTELLIGENT TECHNOLOGY CO., LTD., Suzhou (CN)

(72) Inventor: Fudong LIU, Suzhou (CN)

(73) Assignee: SUZHOU METABRAIN INTELLIGENT TECHNOLOGY CO., LTD., Suzhou (CN)

(21) Appl. No.: 19/051,048

(22) Filed: Feb. 11, 2025

Related U.S. Application Data
(63) Continuation of application No. PCT/CN2023/121783, filed on Sep. 26, 2023.

(30) Foreign Application Priority Data
Jan. 9, 2023 (CN) 202310024633.5

(51) Int. Cl. G11C 7/10

(52) U.S. Cl. CPC G11C 7/1048

(57) ABSTRACT

Disclosed are a hard disk control system and method, and a related component, which relate to the field of hard disks. The hard disk control system includes: a control module, configured to receive operation information, and generate an operation signal and a chip selection signal according to the operation information; and at least one gating module, wherein each gating module includes a plurality of output ports, the plurality of output ports are connected with a plurality of flash loads in a one-to-one correspondence manner, and each gating module is configured to determine a target output port from the plurality of output ports according to the chip selection signal, and transmit the operation signal to the corresponding flash load via the target output port, so that the flash load responds to the operation signal based on the chip selection signal.

### CROSS-REFERENCE TO RELATED APPLICATION

This application is a National Stage Application of International Application No. PCT/CN2023/121783 filed on Sep. 26, 2023, which claims the benefit of Ser. No. 202310024633.5 filed on Jan. 9, 2023 in China, and which applications are incorporated herein by reference. To the extent appropriate, a claim of priority is made to each of the above disclosed applications.

### TECHNICAL FIELD

The present disclosure relates to the field of hard disks, and particularly relates to a hard disk control system and method, and a related component.

### BACKGROUND

Compared with an HDD (hard disk drive), an SSD (solid state disk) has greater advantages in performance such as speed, power consumption, capacity, noise, reliability and the like. In the present stage, although the former has certain advantages in terms of cost, with the occurrence of large-capacity FLASH (flash) particles, the cost of the SSD is lower and lower, and thus SSD can be more widely applied to devices such as servers and storages. At present, all SSD NAND (NAND FLASH in full name) loads are mounted on the same NAND bus, when operations such as read and write are performed on the SSD NANDs, since numerous NAND loads are mounted on the NAND bus, the read-write rate is relatively slow, which is not conducive to improving the market competition of the SSD.

Therefore, how to provide a solution to solve the above technical problems is a problem to be solved by those skilled in the art at present.

### SUMMARY

The objective of the present disclosure is to provide a hard disk control system and method, and a related component, which can reduce the number of flash loads mounted on each NAND bus, implement point-to-point communication between a control module and the flash load, improve a NAND read-write rate, indirectly optimize product performance parameters of an SSD, and improve the competitiveness of the SSD.

In order to solve the above technical problems, according to a first aspect, the present disclosure provides a hard disk control system, including:
a control module, configured to receive operation information, and generate an operation signal and a chip selection signal according to the operation information; and
at least one gating module, wherein each gating module includes a plurality of output ports, the plurality of output ports are connected with a plurality of flash loads in a one-to-one correspondence manner, and each gating module is configured to determine a target output port from the plurality of output ports according to the chip selection signal, and transmit the operation signal to the corresponding flash load via the target output port, so that the flash load responds to the operation signal based on the chip selection signal.

Optionally, each flash load includes a plurality of execution units; and each flash load is configured to select any execution unit according to the chip selection signal to serve as an execution unit for responding to the operation signal.

Optionally, each flash load and the control module are further configured to:
send a channel connection of the chip selection signal;
receive the chip selection signal output by the control module via a channel, so as to select any execution unit according to the chip selection signal to serve as the execution unit for responding to the operation signal, wherein the chip selection signal is valid at a target level.

Optionally, each flash load includes a plurality of execution units, and the gating module is configured to:
acquire the chip selection signal corresponding to each execution unit;
determine an input gating signal based on all chip selection signals; and
determine the target output port from the plurality of output ports according to the input gating signal, and the transmit the operation signal to the corresponding flash load via the target output port.

Optionally, the gating module is further configured to receive a preset correspondence between the chip selection signals and the output ports; and
the process of determining the target output port from the plurality of output ports according to the input gating signal includes:
determining the target output port according to the input gating signal and the correspondence.

Optionally, each flash load includes a plurality of execution units, the gating module includes a logical processing unit and a switch control unit, the switch control unit includes a first port and a plurality of second ports, the first port of the switch control unit is configured to acquire the operation signal generated by the control module, and the second ports serve as the output ports of the gating module; and
the logical processing unit is configured to acquire the chip selection signal corresponding to each execution unit, determine the input gating signal based on all chip selection signals, determine the target output port from the plurality of output ports according to the input gating signal, and control the target output port to communicate with the first port of the switch control unit, so as to transmit the operation signal acquired by the first port of the switch control unit to the flash load connected with the target output port.

Optionally, the hard disk control system further includes:
a first configuration module, connected with a first configuration end of the gating module, and configured to configure the chip selection signal received by the gating module as an input signal.

Optionally, the first configuration module includes a first resistor, a first end of the first resistor is connected with a power supply module, and a second end of the first resistor is connected with the first configuration end.

Optionally, the hard disk control system further includes:
a second configuration module, connected with a second configuration end of the gating module, and configured to configure the functions of the gating module.

Optionally, the second configuration module includes a second resistor and a third resistor, a first end of the second resistor is connected with the power supply module, a second end of the second resistor and a first end of the third resistor are both connected with the second configuration end, and a second end of the third resistor is grounded.

Optionally, the hard disk control system further includes:
a third configuration module, connected with a third configuration end of the gating module, and configured to enable a transmission channel of the gating module.

Optionally, the gating module is a high-speed bus switch.

Optionally, the high-speed bus switch is a high-speed switch chip of which the model number is MX0141KA1.

Optionally, the control module includes a PCIe 3.0 controller.

Optionally, the operation signal includes a read operation signal or a write operation signal or an erase operation signal.

Optionally, the gating module includes a plurality of first ports, each first port of the gating module is configured to receive at least one chip selection signal, and the gating module is configured to:
determine whether there is a valid chip selection signal in the chip selection signals received by each first port;
in a case that there is the valid chip selection signal in the chip selection signals received by each first port, determine a valid input gating signal based on the valid chip selection signal; and
determine the target output port from the plurality of output ports according to the valid input gating signal, and transmit the operation signal to the corresponding flash load via the target output port, so that the flash load responds to the operation signal based on the chip selection signal.

According to a second aspect, the present disclosure further provides a storage system, including the hard disk control system according to any of the foregoing.

According to a third aspect, the present disclosure further provides a server system, including the hard disk control system according to any of the foregoing.

According to a fourth aspect, the present disclosure further provides a hard disk control method, applied to the hard disk control system according to any of the foregoing, wherein the hard disk control method includes:
acquiring a chip selection signal and an operation signal generated based on operation information;
determining a target output port from all output ports of a gating module according to the chip selection signal; and
transmitting the operation signal to a corresponding flash load via the target output port, so that the flash load responds to the operation signal based on the chip selection signal.

According to a fifth aspect, the present disclosure further provides an electronic device, including:
a memory, configured to store a computer program; and
a processor, configured to implement the steps of the hard disk control method as described above when executing the computer program.

According to a sixth aspect, the present disclosure further provides a non-transitory readable storage medium, wherein a computer program is stored on the non-transitory readable storage medium, and when executed by a processor, the computer program implements the steps of the hard disk control method as described above.

The present disclosure provides a hard disk control system, the plurality of output ports of the gating module are connected with the plurality of flash loads in the one-to-one correspondence manner, the target output port is determined according to the chip selection signal, and the operation signal is only sent to the flash load connected with the target output port. In this way, on one hand, the number of flash loads mounted on each NAND bus is reduced, and on the other hand, point-to-point communication between the control module and the flash load is implemented, thereby improving a NAND read-write rate, indirectly optimizing product performance parameters of an SSD, and improving the competitiveness of the SSD. The present disclosure further provides a hard disk control method, a server system, a storage system, an electronic device and a non-transitory readable storage medium, which have the same beneficial effects as the hard disk control system.

### BRIEF DESCRIPTION OF THE DRAWINGS

To illustrate technical solutions in the embodiments of the present disclosure more clearly, a brief introduction on the drawings which are needed in the description of the embodiments is given below. Apparently, the drawings in the description below are merely optional embodiments of the present disclosure, and those ordinary skilled in the art may obtain other drawings according to these drawings without any creative effort.

FIG. 1 is a schematic structural diagram of a hard disk control system provided in the present disclosure;

FIG. 2 is a schematic structural diagram of another hard disk control system provided in the present disclosure;

FIG. 3 is a schematic topological diagram of a NAND disclosure of an 8 TB-capacity point provided in the present disclosure;

FIG. 4 is a schematic diagram of high-speed bus control logic of a high-speed bus switch provided in the present disclosure;

FIG. 5 is a flowchart of steps of a hard disk control method provided in the present disclosure;

FIG. 6 is a structural block diagram of a hard disk control system provided in the present application;

FIG. 7 is a block diagram of a hardware structure of an internal die of a NAND package provided in the present application; and

FIG. 8 is a block diagram of a hardware structure of configuring the chip selection signal inside the high-speed bus gating module provided in the present application.

### DETAILED DESCRIPTION OF THE INVENTION

The core of the present disclosure is to provide a hard disk control system and method, and a related component, which may reduce the number of flash loads mounted on each NAND (NotAnd) bus, implement point-to-point communication between a control module and the flash load, improve a NAND read-write rate, indirectly optimize product performance parameters of an SSD (solid state disk), and improve the competitiveness of the SSD.

In order to make the objectives, technical solutions and advantages of the embodiments of the present disclosure clearer, a clear and complete description of technical solutions in the embodiments of the present disclosure will be given below, in combination with the drawings in the embodiments of the present disclosure. Apparently, the embodiments described below are merely optional embodiments of the present disclosure instead of all embodiments. Embodiments obtained by those ordinary skilled in the art based on the embodiments in the present disclosure without any creative effort fall into the protection scope of the present disclosure.

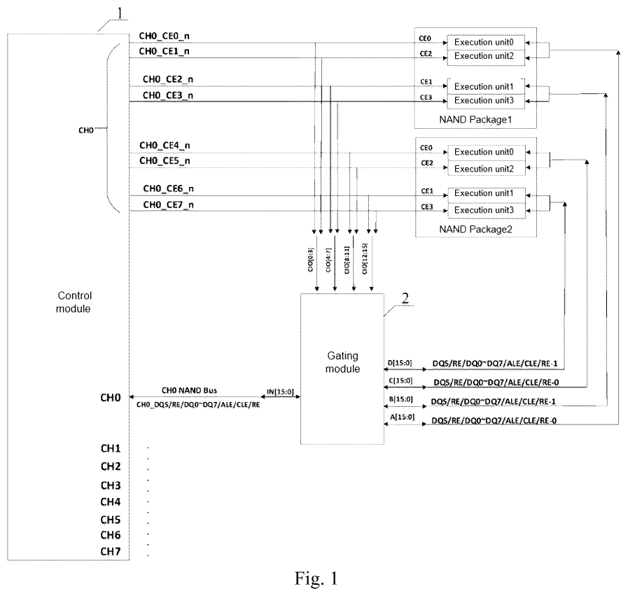

In a first aspect, referring to FIG. 1, FIG. 1 is a schematic structural diagram of a hard disk control system provided in the present disclosure, wherein the hard disk control system includes:
a control module 1, configured to receive operation information, and generate an operation signal and a chip selection signal according to the operation information; and
at least one gating module 2, wherein each gating module 2 includes a plurality of output ports, the plurality of output ports are connected with a plurality of flash loads in a one-to-one correspondence manner, and each gating module 2 is configured to determine a target output port from the plurality of output ports according to the chip selection signal, and transmit the operation signal to the corresponding flash load via the target output port, so that the flash load responds to the operation signal based on the chip selection signal.

Optionally, the control module 1 is configured to receive the operation information, wherein the operation information may include a flash load to be operated, and an operation to be performed on the flash load, for example, it is necessary to read information in a certain flash load or write related content into a certain flash load, etc. The control module 1 generates the chip selection signal and the operation signal based on the operation information, wherein the chip selection signal is used for selecting a flash load, the operation signal is used for controlling the selected flash load to execute a corresponding operation, and the operation signal includes, but is not limited to, a read operation signal or a write operation signal or an erase operation signal.

It can be understood that the number of gating modules 2 may be determined based on the number of control channels of the control module 1, for example, regarding to a control module 1 having eight channels, at least eight gating modules 2 may be adaptively provided. Each gating module 2 includes a plurality of output ports, and the number of output ports may be determined according to the number of flash loads of a hard disk module, for example, in the case that the hard disk module is a U.2 NVMe (Non-Volatile Memory express, non-volatile memory management host system controller through interface technical specifications) SSD, which includes four flash loads, then the gating module 2 may be provided with at least four output ports, each output port is connected with each flash load via one NAND bus, that is, one flash load is mounted on each NAND bus. According to the chip selection signal output by the control module 1, the gating module 2 may determine the flash load to be operated, so as to determine the target output port from the plurality of output ports, the target output port is connected with the flash load to be operated, and the operation signal is sent from the target output port to the flash load to be operated via the NAND bus. Since only one flash load is mounted on the NAND bus, point-to-point communication between the control module and the flash load is implemented, and the NAND read, write and erase rates are improved.

The present disclosure provides a hard disk control system, the plurality of output ports of the gating module 2 are connected with the plurality of flash loads in the one-to-one correspondence manner, the target output port is determined according to the chip selection signal, and the operation signal is only sent to the flash load connected with the target output port. In this way, on one hand, the number of flash loads mounted on each NAND bus is reduced, and on the other hand, point-to-point communication between the control module 1 and the flash load is implemented, thereby improving a NAND read-write rate, indirectly optimizing product performance parameters of an SSD, and improving the competitiveness of the SSD.

### BASED ON THE ABOVE EMBODIMENT

In an embodiment, each flash load includes a plurality of execution units; and
each flash load is configured to select any execution unit according to the chip selection signal to serve as an execution unit for responding to the operation signal.

In an embodiment, each flash load includes a plurality of execution units, and the gating module 2 is configured to:
acquire the chip selection signal corresponding to each execution unit;
determine an input gating signal based on all chip selection signals; and
determine the target output port from the plurality of output ports according to the input gating signal, and the transmit the operation signal to the corresponding flash load via the target output port.

It can be understood that each flash load may include a plurality of execution units, taking a NAND load as an example, one NAND load may include a plurality of NAND Targets, one NAND Target is one execution unit, and the control module 1 may select a certain execution unit in the NAND load based on the operation information to respond to the corresponding operation signal, the control module 1 outputs the chip selection signal corresponding to each execution unit based on the operation information, the chip selection signal may be a high-level signal or a low-level signal, and in the case that the chip selection signal is valid at a low level, the execution unit receiving the low-level signal is a selected execution unit, and after the operation signal reaches the flash load via the NAND bus, the selected execution unit responds to the operation signal.

The gating module 2 may determine the flash load on which the selected execution unit is located according to the chip selection signal sent to each execution unit, and it can be understood that each flash load corresponds to one input gating signal, so that the gating module 2 may determine the target output port connected with the selected flash load according to the input gating signal.

In an embodiment, the gating module 2 is further configured to receive a preset correspondence between the chip selection signals and the output ports; and
the process of determining the target output port from the plurality of output ports according to the input gating signal includes:
determining the target output port according to the input gating signal and the correspondence.

It can be understood that, in order to improve a read-write rate at a NAND rear end, the correspondence between each input chip selection signal and the target output port may be preset, for example, a target output port corresponding to an input gating signal CIO1 is a Port A, a target output port corresponding to an input gating signal CIO2 is a Port (port) B, a target output port corresponding to an input gating signal CIO3 is a Port C, a target output port corresponding to an input gating signal CIO4 is a Port D, when it is determined based on all chip selection signals Ce0 to Cen that the input chip selection signal is CIO2, the Port B is directly determined as the target output port, and the operation signal is transmitted via the Port B.

In an embodiment, each flash load includes a plurality of execution units, the gating module 2 includes a logical processing unit and a switch control unit, the switch control unit includes a first port and a plurality of second ports, the first port is configured to acquire the operation signal generated by the control module 1, and the second ports serve as the output ports of the gating module 2; and
the logical processing unit is configured to acquire the chip selection signal corresponding to each execution unit, determine the input gating signal based on all chip selection signals, determine the target output port from the plurality of output ports according to the input gating signal, and control the target output port to communicate with the first port, so as to transmit the operation signal acquired by the first port to the flash load connected with the target output port.

Optionally, the gating module 2 may include the logical processing unit and the switch control unit, the first port of the switch control unit is connected with a control channel of the control module 1 and is configured to receive the operation signal output by the control module 1, the switch control unit further includes a plurality of output ports, an on-off state between the input port and each output port is controlled by the logical processing unit, and after determining the target output port, the logical processing unit may connect the target output port with the input port, and disconnect the input port from the other output ports, so as to transmit the operation signal via only one output port.

In an embodiment, the hard disk control system further includes:
a first configuration module, connected with a first configuration end of the gating module 2, and configured to configure the chip selection signal received by the gating module 2 as an input signal.

In an embodiment, the first configuration module includes a first resistor, a first end of the first resistor is connected with a power supply module, and a second end of the first resistor is connected with the first configuration end.

Optionally, the gating module 2 includes a plurality of second ports, configured to receive an input chip selection signal, and the first configuration end of the gating module 2 is used for selecting whether the second port of the gating module 2 is used as the input port or the output port. In the present embodiment, the second port of the gating module 2 is configured as the input port via a pull-up resistor, that is, the chip selection signal received by the gating module 2 is determined as the input signal for subsequent processing.

In an embodiment, the hard disk control system further includes:
a second configuration module, connected with a second configuration end of the gating module 2, and configured to configure the functions of the gating module 2.

In an embodiment, the second configuration module includes a second resistor and a third resistor, a first end of the second resistor is connected with the power supply module, a second end of the second resistor and a first end of the third resistor are both connected with the second configuration end, and a second end of the third resistor is grounded.

Optionally, the second configuration end is used for configuring the functions of a high-speed signal interface and a low-speed control signal.

In an embodiment, the hard disk control system further includes:
a third configuration module, connected with a third configuration end of the gating module 2, and configured to enable a transmission channel of the gating module 2.

The third configuration end is configured to enable a device and enable each output channel, and to perform pull-down processing by default.

In an embodiment, the gating module 2 is a high-speed bus switch.

In an embodiment, the high-speed bus switch is a high-speed switch chip of which the model number is MX0141KA1.

In an embodiment, the control module 1 includes a PCIe (Peripheral Component Interconnect Express) 3.0 controller.

In an embodiment, the gating module 2 includes a plurality of first ports, each first port of the gating module is configured to receive at least one chip selection signal, and the gating module 2 is configured to:
determine whether there is a valid chip selection signal in the chip selection signals received by each first port;
in a case that there is the valid chip selection signal in the chip selection signals received by each first port, determine a valid input gating signal based on the valid chip selection signal; and
determine the target output port from the plurality of output ports according to the valid input gating signal, and transmit the operation signal to the corresponding flash load via the target output port, so that the flash load responds to the operation signal based on the chip selection signal.

The valid chip selection signal may be a low-level signal or a high-level signal, for example, it is assumed that the valid chip selection signal is a low-level signal, among a plurality of chip selection signals generated by the control module 1, only the chip selection signal sent to the selected execution unit is a low-level signal, and in the case that all the chip selection signals in the same flash load are connected with one first port of the gating module 2, whether the input gating signal of the first port is valid may be determined according to whether there is a low-level signal in the chip selection signals acquired by the first port, so as to determine that the output port corresponding to the valid input gating signal is the target output port.

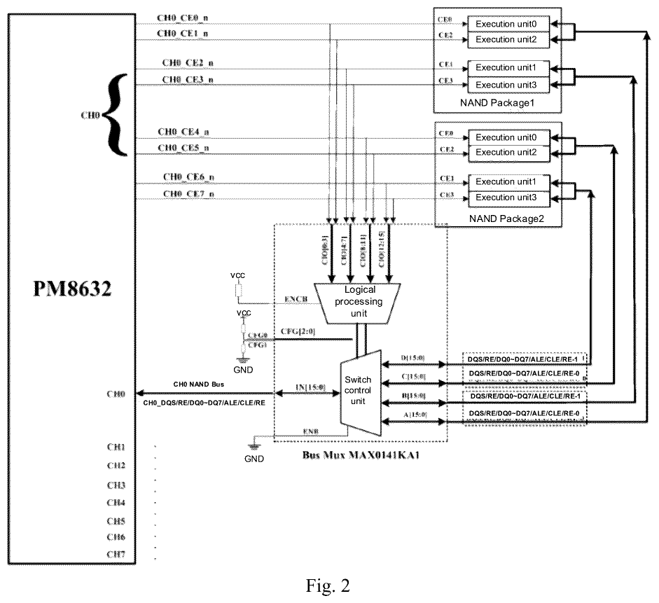

For ease of understanding the solution of the present disclosure, referring to FIG. 2, the solution of the present disclosure is described in detail with reference to FIG. 2 by taking it an example that the hard disk is a U.2 NVMe SSD, the control module 1 is a Microchip PCIe3.0 controller PM8632, and that the gating module 2 is a high-speed bus switch MX0141KA1.

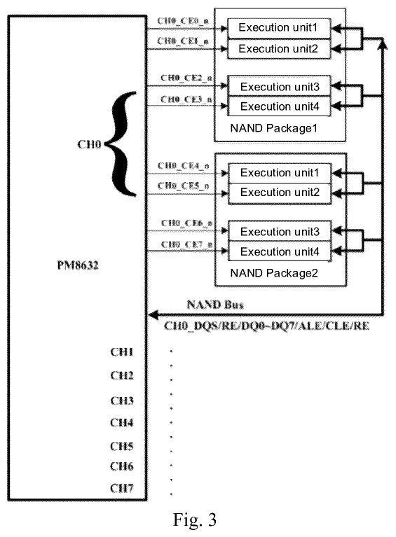

Optionally, the Microchip PCIe3.0 controller PM8632 is an 8-channel controller, and each channel supports 8 CEs (CE, chip enable, which is used for selecting a target of a NAND Flash, that is, the chip selection signal). In a conventional manner, in the case that an 8 TB-capacity point disk is implemented, then all the 8 CEs of each channel of the controller need to support the 8 CEs of the NAND Flash, a hardware connection corresponds to 2 pcs NAND (each NAND has 4 targets, each target includes 2 dies, the capacity of each die is 512 GB, and the capacity of a single pcs NAND is 512 GB), each channel corresponds to 1 TB, 8 channels are combined into an 8-TB overall capacity space, and the hardware disclosure topology thereof is shown in FIG. 3. The NAND high-speed lines (DQS/RE/DQ0-DQ7, or the like) of such a channel are connected with four groups of NAND buses in parallel, in which the NAND topology maximally supports a rate of 533 Mbps due to the effects of NAND capacitive loads. In order to reduce the effects of parallel NAND capacitive loads, in the present disclosure, a high-speed bus switch is added between an SSD main control (i.e., the control module 1) and the NAND, and it is ensured, by means of software and hardware switching of 1:4 high-speed buses, that the NAND high-speed bus of the controller is only connected with a group of NAND buses at any moment, thereby improving the NAND communication rate.

CE signals CE0_n to CE7_n of each channel of the control module 1 are respectively connected with eight groups of CE signals of the NAND and CIO signals of the high-speed switch chip, on one hand, the CE target of 2 pcs NAND is selected, and on the other hand, channel selection between a high-speed input IN [15:0] and a high-speed signal output A [15:0]/B [15:0]/C [15:0]/D [15:0] is controlled by a CIO function, and an ENCB pin is used for selecting whether to enable the CIO [15:0] as an output signal and pulling the same to a high level to serve as an input signal; an ENB pin is used for enabling a device and a A/B/C/D channel, and is pulled to a low level for processing by default; and a CFG [2:0] pin is set as a function configuration pin of the high-speed signal interface and the low-speed control signal, and in the present solution, CFG0 is used for pulling up the high level, and CFG1 is used for pulling down the low level.

In the present embodiment, the CE signals CE0_n to CE7_n of each channel are respectively connected with eight groups of CE signals of the NAND and the CIO signals of the high-speed switch chip, for example, CH0_CE0_n is simultaneously connected with a CE0 signal of a NAND package 1 end and a CIO [0] signal of the MX0141KA1 chip; CH0_CE1_n is simultaneously connected with a CE2 signal of the NAND package 1 end and a CIO [0] signal of the MX0141KA1 chip; CH0_CE0_4 is simultaneously connected with a CE1 signal of the NAND package 1 end and a CIO [4] signal of the MX0141KA1 chip; CH0_CE5_n is simultaneously connected with a CE3 signal of the NAND package 1 end and a CIO [5] signal of the MX0141KA1 chip; and the hardware connections of the remaining NAND package 2 are similar, and a mapping connection relationship thereof is shown in Table 1.

TABLE 1
Mapping Connection Relationship

| CH0_C | CH0_C | | CH0_C | CH0_C | | CH0_C | CH0_C | | CH0_C | CH0_C | |
|---|---|---|---|---|---|---|---|---|---|---|---|
| E0_n | E1_n | | E2_n | E3_n | | E4_n | E5_n | | E6_n | E7_n | |
| CE0 | CE2 | NAND1 | CE1 | CE3 | NAND1 | CE0 | CE2 | NAND2 | CE1 | CE3 | NAND2 |
| CIO[0] | CIO[1] | A port | CIO[4] | CIO[5] | B port | CIO[8] | CIO[9] | C port | CIO[12] | CIO[13] | D port |
| 0 | 1 | IN | 0 | 1 | IN | 0 | 1 | IN | 0 | 1 | IN |
| 1 | 0 | IN | 1 | 0 | IN | 1 | 0 | IN | 1 | 0 | IN |

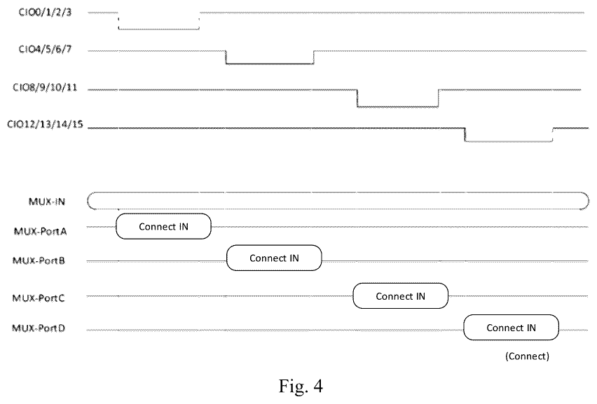

In the present embodiment, DQ0-DQ7/DQS/RE/ALE/CLE/WE signals of a controller end are connected with IN [15:0] signals of the bus switch in a one-to-one correspondence manner, and only 15 groups of signals therein are used in the disclosure; 4 groups of port buses, that is, A port, B port, C port and D port buses, of the high-speed bus switch are respectively connected with four groups of NAND buses of the NAND package 1/NAND package 2; when CIO [0] or CIO [1] is at a low level, the IN [15:0] selects the port A; when CIO [4] or CIO [5] is at a low level, the IN [15:0] selects the port B; when CIO [8] or CIO [9] is at a low level, the IN [15:0] selects the port C; when CIO [12] or CIO [13] is at a low level, the IN [15:0] selects the port D; and the bus control logic of the high-speed bus switch is shown in FIG. 4.

In combination with the hardware electric connection block diagrams in FIG. 2, FIG. 3 and Table 1, and the control logic of the chip, when the CH0_CE0_n signal of the SSD controller end outputs a low level and the CH0_CE1_n signal outputs a high level, the CE0 signal of the NAND package 1 is selected, and the CIO [0] input signal of the corresponding high-speed bus chip MX0141KA1 is at a low level, at this time, the NAND 15 groups of high-speed signals of the CH0 of the SSD controller end reach the A port via the high-speed bus switch, and then reach the bus of the NAND package 1, so as to implement read, write and erase operations of the CH0 and the bus of the NAND package 1 and to implement a related operation of target 0 in the NAND package 1, and at this time, the SSD controller end performs point-to-point communication with the NAND end; and when the CH0_CE0_n signal of the SSD controller end outputs a high level and the CH0_CE1_n signal outputs a low level, the CE2 signal of the NAND package 1 is selected, and the CIO [1] input signal of the corresponding high-speed bus chip MX0141KA1 is at a low level, at this time, the NAND 15 groups of high-speed signals of the CH0 of the SSD controller end also reach the A port via the high-speed switch chip, and then reach the bus of the NAND package 1, so as to implement the read, write and erase operations of the CH0 and the bus of the NAND package 1 and to implement a related operation of target 2 in the NAND package1, and at this time, the SSD controller end also performs point-to-point communication with the NAND end. With regard to the control logic of CH0_CE2_n to CH0_CE7_n signals, and the selections of the CIO [4]/CIO [5]/CIO [8]/CIO [9]/CIO [12]/CIO [13] of the high-speed bus chip MX0141KA1 and the CE0/CE2/CE1/CE3 of the NAND are similar to the above process, thus details are not repeated herein again.

In summary, by means of the above hardware design scheme and software and hardware logic control, the present disclosure reduces capacitive loads of one NAND high-speed channel, and optimizes 1:4 bus topology to point-to-point communication of 1:1 bus; and by actual simulation verification, the NAND interface rate is increased from 533 Mbps to 800 Mbps, so that the interface rate is increased by nearly 50%, thus improving the bandwidth of NAND communication, and indirectly optimizing the product performance of the SSD.

In a second aspect, the present disclosure further provides a storage system, including the hard disk control system described in the above optional embodiments.

The hard disk control system includes:
a control module, configured to receive operation information, and generate an operation signal and a chip selection signal according to the operation information; and
at least one gating module, wherein each gating module includes a plurality of output ports, the plurality of output ports are connected with a plurality of flash loads in a one-to-one correspondence manner, and each gating module is configured to determine a target output port from the plurality of output ports according to the chip selection signal, and transmit the operation signal to the corresponding flash load via the target output port, so that the flash load responds to the operation signal based on the chip selection signal.

In the present embodiment, the plurality of output ports of the gating module are connected with the plurality of flash loads in the one-to-one correspondence manner, the target output port is determined according to the chip selection signal, and the operation signal is only sent to the flash load connected with the target output port. In this way, on one hand, the number of flash loads mounted on each NAND bus is reduced, and on the other hand, point-to-point communication between the control module and the flash load is implemented, thereby improving the NAND read-write rate, indirectly optimizing product performance parameters of the SSD, and improving the competitiveness of the SSD.

In an embodiment, each flash load includes a plurality of execution units; and
each flash load is configured to select any execution unit according to the chip selection signal to serve as an execution unit for responding to the operation signal.

In an embodiment, each flash load includes a plurality of execution units, and the gating module is configured to:
acquire the chip selection signal corresponding to each execution unit;
determine an input gating signal based on all chip selection signals; and
determine the target output port from the plurality of output ports according to the input gating signal, and the transmit the operation signal to the corresponding flash load via the target output port.

In an embodiment, the gating module is further configured to receive a preset correspondence between the chip selection signals and the output ports; and the process of determining the target output port from the plurality of output ports according to the input gating signal includes:
determining the target output port according to the input gating signal and the correspondence.

In an embodiment, each flash load includes a plurality of execution units, the gating module includes a logical processing unit and a switch control unit, the switch control unit includes a first port and a plurality of second ports, the first port is configured to acquire the operation signal generated by the control module, and the second ports serve as the output ports of the gating module; and
the logical processing unit is configured to acquire the chip selection signal corresponding to each execution unit, determine the input gating signal based on all chip selection signals, determine the target output port from the plurality of output ports according to the input gating signal, and control the target output port to communicate with the first port, so as to transmit the operation signal acquired by the first port to the flash load connected with the target output port.

In an embodiment, the hard disk control system further includes:
a first configuration module, connected with a first configuration end of the gating module, and configured to configure the chip selection signal received by the gating module as an input signal.

In an embodiment, the first configuration module includes a first resistor, a first end of the first resistor is connected with a power supply module, and a second end of the first resistor is connected with the first configuration end.

In an embodiment, the hard disk control system further includes:
a second configuration module, connected with a second configuration end of the gating module, and configured to configure the functions of the gating module.

In an embodiment, the second configuration module includes a second resistor and a third resistor, a first end of the second resistor is connected with the power supply module, a second end of the second resistor and a first end of the third resistor are both connected with the second configuration end, and a second end of the third resistor is grounded.

In an embodiment, the hard disk control system further includes:
a third configuration module, connected with a third configuration end of the gating module, and configured to enable a transmission channel of the gating module.

In an embodiment, the gating module is a high-speed bus switch.

In an embodiment, the high-speed bus switch is a high-speed switch chip of which the model number is MX0141KA1.

In an embodiment, the control module includes a PCIe 3.0 controller.

In an embodiment, the operation signal includes a read operation signal or a write operation signal or an erase operation signal.

In an embodiment, the gating module includes a plurality of first ports, each first port of the gating module is configured to receive at least one chip selection signal, and the gating module is configured to:
determine whether there is a valid chip selection signal in the chip selection signals received by each first port;
in a case that there is the valid chip selection signal in the chip selection signals received by each first port, determine a valid input gating signal based on the valid chip selection signal; and
determine the target output port from the plurality of output ports according to the valid input gating signal, and transmit the operation signal to the corresponding flash load via the target output port, so that the flash load responds to the operation signal based on the chip selection signal.

In a third aspect, the present disclosure further provides a server system, including the hard disk control system described in the above optional embodiments.

The hard disk control system includes:
a control module, configured to receive operation information, and generate an operation signal and a chip selection signal according to the operation information; and
at least one gating module, wherein each gating module includes a plurality of output ports, the plurality of output ports are connected with a plurality of flash loads in a one-to-one correspondence manner, and each gating module is configured to determine a target output port from the plurality of output ports according to the chip selection signal, and transmit the operation signal to the corresponding flash load via the target output port, so that the flash load responds to the operation signal based on the chip selection signal.

In the present embodiment, the plurality of output ports of the gating module are connected with the plurality of flash loads in the one-to-one correspondence manner, the target output port is determined according to the chip selection signal, and the operation signal is only sent to the flash load connected with the target output port. In this way, on one hand, the number of flash loads mounted on each NAND bus is reduced, and on the other hand, point-to-point communication between the control module and the flash load is implemented, thereby improving the NAND read-write rate, indirectly optimizing product performance parameters of the SSD, and improving the competitiveness of the SSD.

In an embodiment, each flash load includes a plurality of execution units; and
each flash load is configured to select any execution unit according to the chip selection signal to serve as an execution unit for responding to the operation signal.

In an embodiment, each flash load includes a plurality of execution units, and the gating module is configured to:
acquire the chip selection signal corresponding to each execution unit;
determine an input gating signal based on all chip selection signals; and
determine the target output port from the plurality of output ports according to the input gating signal, and the transmit the operation signal to the corresponding flash load via the target output port.

In an embodiment, the gating module is further configured to receive a preset correspondence between the chip selection signals and the output ports; and
the process of determining the target output port from the plurality of output ports according to the input gating signal includes:
determining the target output port according to the input gating signal and the correspondence.

In an embodiment, each flash load includes a plurality of execution units, the gating module includes a logical processing unit and a switch control unit, the switch control unit includes a first port and a plurality of second ports, the first port is configured to acquire the operation signal generated by the control module, and the second ports serve as the output ports of the gating module; and
the logical processing unit is configured to acquire the chip selection signal corresponding to each execution unit, determine the input gating signal based on all chip selection signals, determine the target output port from the plurality of output ports according to the input gating signal, and control the target output port to communicate with the first port, so as to transmit the operation signal acquired by the first port to the flash load connected with the target output port.

In an embodiment, the hard disk control system further includes:
a first configuration module, connected with a first configuration end of the gating module, and configured to configure the chip selection signal received by the gating module as an input signal.

In an embodiment, the first configuration module includes a first resistor, a first end of the first resistor is connected with a power supply module, and a second end of the first resistor is connected with the first configuration end.

In an embodiment, the hard disk control system further includes:
a second configuration module, connected with a second configuration end of the gating module, and configured to configure the functions of the gating module.

In an embodiment, the second configuration module includes a second resistor and a third resistor, a first end of the second resistor is connected with the power supply module, a second end of the second resistor and a first end of the third resistor are both connected with the second configuration end, and a second end of the third resistor is grounded.

In an embodiment, the hard disk control system further includes:
a third configuration module, connected with a third configuration end of the gating module, and configured to enable a transmission channel of the gating module.

In an embodiment, the gating module is a high-speed bus switch.

In an embodiment, the high-speed bus switch is a high-speed switch chip of which the model number is MX0141KA1.

In an embodiment, the control module includes a PCIe 3.0 controller.

In an embodiment, the operation signal includes a read operation signal or a write operation signal or an erase operation signal.

In an embodiment, the gating module includes a plurality of first ports, each first port of the gating module is configured to receive at least one chip selection signal, and the gating module is configured to:
determine whether there is a valid chip selection signal in the chip selection signals received by each first port;
in a case that there is the valid chip selection signal in the chip selection signals received by each first port, determine a valid input gating signal based on the valid chip selection signal; and
determine the target output port from the plurality of output ports according to the valid input gating signal, and transmit the operation signal to the corresponding flash load via the target output port, so that the flash load responds to the operation signal based on the chip selection signal.

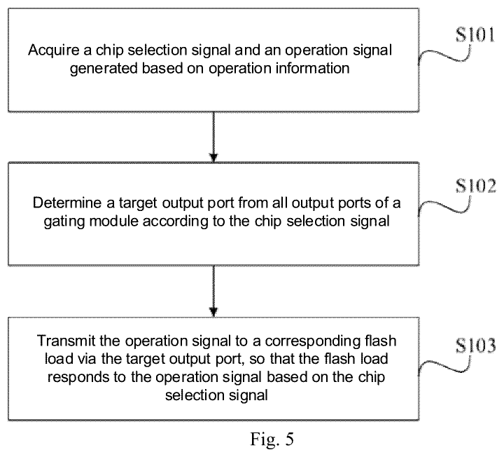

In a fourth aspect, referring to FIG. 5, FIG. 5 is a hard disk control method further provided in the present disclosure, which is applied to the hard disk control system according to any of the foregoing, wherein the hard disk control method includes:
S101: acquiring a chip selection signal and an operation signal generated based on operation information;
S102: determining a target output port from all output ports of a gating module according to the chip selection signal; and
S103: transmitting the operation signal to a corresponding flash load via the target output port, so that the flash load responds to the operation signal based on the chip selection signal.

In the present embodiment, a plurality of output ports of the gating module in the hardware control system are connected with a plurality of flash loads in a one-to-one correspondence manner, the target output port is determined according to the chip selection signal, and the operation signal is only sent to the flash load connected with the target output port. In this way, on one hand, the number of flash loads mounted on each NAND bus is reduced, and on the other hand, point-to-point communication between a control module and the flash load is implemented, thereby improving the NAND read-write rate, indirectly optimizing product performance parameters of the SSD, and improving the competitiveness of the SSD.

In an embodiment, each flash load includes a plurality of execution units, and the process of acquiring the chip selection signal generated based on the operation information includes:
acquiring the chip selection signal that is generated based on the operation information and corresponds to each execution unit;
wherein the process of determining the target output port from all output ports of the gating module of the hardware control system according to the chip selection signal includes:
determining an input gating signal based on all chip selection signals; and
determining the target output port from the plurality of output ports according to the input gating signal.

In an embodiment, the method further includes:
receiving a preset correspondence between the chip selection signals and the output ports; and
the process of determining the target output port from the plurality of output ports according to the input gating signal includes:
determining the target output port according to the input gating signal and the correspondence.

In an embodiment, the hardware control method further includes:
upon receiving first configuration information, configuring the chip selection signal received by the gating module as an input signal.

In an embodiment, the hardware control method further includes:
upon receiving second configuration information, configuring the functions of the gating module.

In an embodiment, the gating module includes a plurality of first ports, and each first port of the gating module is configured to receive at least one chip selection signal;
wherein the process of determining the target output port from all the output ports of the gating module according to the chip selection signal includes:
determining whether there is a valid chip selection signal in the chip selection signals received by each first port;
in a case that there is the valid chip selection signal in the chip selection signals received by each first port, determining a valid input gating signal based on the valid chip selection signal; and
determining the target output port from the plurality of output ports according to the valid input gating signal.

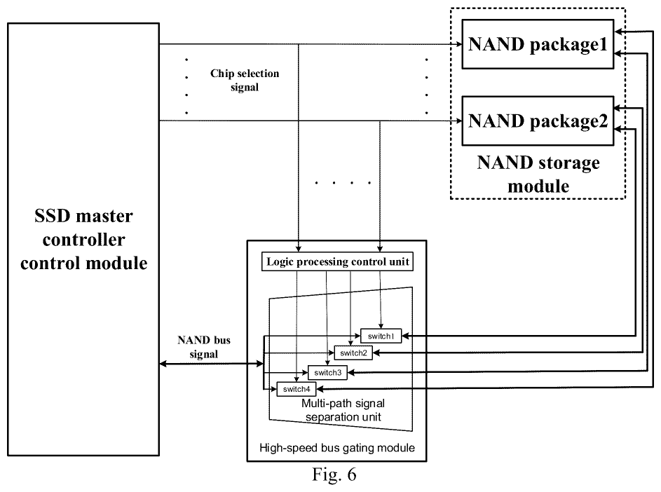

FIG. 6 is a structural block diagram of a hard disk control system provided in the present application. As shown in FIG. 6, in the present embodiment, a control module of a hard disk control system applied by a hard disk control method may be an SSD master controller control module, which is configured to implement the above step S101. The gating module may be a high-speed bus gating module, which is configured to implement the above steps S102 and S103. The flash load corresponding to a target output port may be a NAND storage module.

In an embodiment, as shown in FIG. 6, the high-speed bus gating module may include a logic processing control unit and a multi-path signal separation unit.

When the SSD master controller control module outputs a CE chip selection signal to the NAND storage module, the CE chip selection signal also acts on the logic processing control processing unit of the high-speed bus gating module, and under related signal logic of the logic processing control unit, NAND high-speed buses output from the SSD master controller control module are electrically connected with die storage units inside the NAND storage module in a one-to-one correspondence manner via the multi-path signal separation unit. In this way, at the same moment, each group of NAND high-speed buses of each channel of the SSD master controller control module performs point-to-point communication with the die storage units inside the NAND storage module, thereby reducing capacitive loads on the buses and improving the rate.

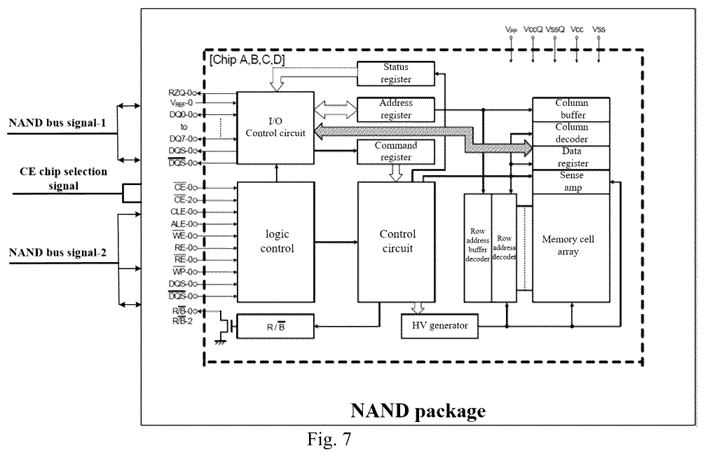

FIG. 7 is a block diagram of a hardware structure of an internal die of a NAND package provided in the present application. As shown in FIG. 7, in the present embodiment, the SSD master controller control module sends the CE chip selection signal to the NAND storage module, and the chip selection signal controls the gating of certain one or two internal die storage units via a logic control unit inside the NAND package. Meanwhile, a NAND bus (a NAND command signal, an address signal and a data signal) after passing through the high-speed bus gating module acts on a storage unit inside a specific die to implement operations, such as read, write and erase, of a NAND storage unit of the specific die.

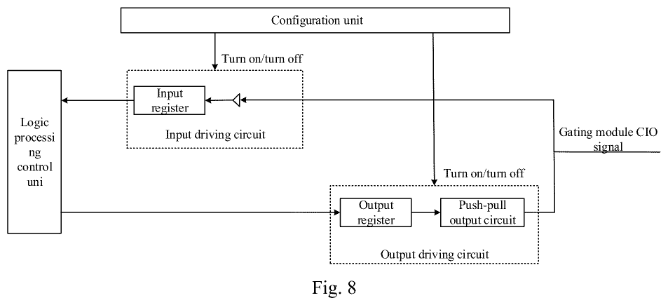

FIG. 8 is a block diagram of a hardware structure of configuring the chip selection signal inside the high-speed bus gating module provided in the present application. As shown in FIG. 8, in the present embodiment, the chip selection signal received by the gating module is configured as an input signal (in addition, in other embodiment scenarios, the signal may be configured as an output signal), and the state of an ENCB interface of the gating module determines, according to an internal configuration mode, whether to configure a CIO interface as an input pin or an output pin. When the state of the ENCB interface is at a low level, a configuration unit turns off an input driving unit and turns on an output driving unit, that is, transmits output data to a CIO signal port of the gating module through an output register and a push-pull output circuit; and when the state of the ENCB interface is at a high level, the configuration unit turns off the output driving unit and turns on the input driving unit, that is, transmits data received by the CIO signal port to the logic processing control unit through an input register. Similarly, the CFG [2:0] interface of the gating module is used for managing function configurations of a high-speed signal interface and a low-speed control signal, which also needs to be completed by the internal logic processing control unit; a one-to-one correspondence between the CIO signal port and NAND bus switching is implemented by state situations of the CFG [2:0] interface, that is, when CIO [0]/CIO [1] is at a low level, an IN port is in signal point-to-point connection with an A port; when CIO [2]/CIO [3] is at a low level, the IN port is in point-to-point connection with a B port; when CIO [4]/CIO [5] is at a low level, the IN port is in point-to-point connection with a C port; and when CIO [6]/CIO [7] is at a low level, the IN port is in point-to-point connection with a D port.

In the present embodiment, the SSD master controller control module may be a controller of a hardware interface such as SAS, SATA or PCIe4.0, a NAND channel interface may be 8 channels or 16 channels, and other private customized 17 or 18 channels. The high-speed bus gating module may use MX0141KA1. The NAND package in the NAND storage module may be any NAND particle, such as Kioxia, Samsung, WDC, Hynix, Micron, YMTC, and the like, and in the embodiment of the present application, the connection mode of the CE chip selection signal and an NAND high-speed signal between the SSD master controller control module and the high-speed bus gating module, and the signal connection mode between the high-speed bus gating module and the NAND storage module may also be applied to other SSD hard disk control systems.

In a fifth aspect, the present disclosure further provides an electronic device, including:
a memory, configured to store a computer program; and
a processor, configured to implement the steps of the hard disk control method described in the optional embodiments when executing the computer program.

Optionally, the memory includes a non-transitory readable storage medium and an internal memory. The non-transitory readable storage medium stores an operating system and a computer-readable instruction, and the internal memory provides an environment for the operation of the operating system and the computer-readable instruction in the non-transitory readable storage medium. The processor provides computation and control capabilities for an on-board navigation apparatus, and may implement the following steps when executing the computer program stored in the memory: acquiring a chip selection signal and an operation signal generated based on operation information; determining a target output port from all output ports of a gating module according to the chip selection signal; and transmitting the operation signal to a corresponding flash load via the target output port, so that the flash load responds to the operation signal based on the chip selection signal.

In the present embodiment, a plurality of output ports of the gating module in a hardware control system are connected with a plurality of flash loads in a one-to-one correspondence manner, the target output port is determined according to the chip selection signal, and the operation signal is only sent to the flash load connected with the target output port. In this way, on one hand, the number of flash loads mounted on each NAND bus is reduced, and on the other hand, point-to-point communication between a control module and the flash load is implemented, thereby improving the NAND read-write rate, indirectly optimizing product performance parameters of the SSD, and improving the competitiveness of the SSD.

In an embodiment, when executing a computer sub-program stored in the memory, the processor may implement the following steps: acquiring the chip selection signal that is generated based on the operation information and corresponds to each execution unit; determining an input gating signal based on all chip selection signals; and determining the target output port from the plurality of output ports according to the input gating signal.

In an embodiment, when executing the computer sub-program stored in the memory, the processor may implement the following steps: receiving a preset correspondence between the chip selection signals and the output ports; and determining the target output port according to the input gating signal and the correspondence.

In an embodiment, when executing the computer sub-program stored in the memory, the processor may implement the following step: upon receiving first configuration information, configuring the chip selection signal received by the gating module as an input signal.

In an embodiment, when executing the computer sub-program stored in the memory, the processor may implement the following step: upon receiving second configuration information, configuring the functions of the gating module.

In an embodiment, when executing the computer sub-program stored in the memory, the processor may implement the following steps: determining whether there is a valid chip selection signal in the chip selection signals received by each first port; in a case that there is the valid chip selection signal in the chip selection signals received by each first port, determining a valid input gating signal based on the valid chip selection signal; and determining the target output port from the plurality of output ports according to the valid input gating signal.

In a sixth aspect, the present disclosure further provides a non-transitory readable storage medium, wherein a computer program is stored on the non-transitory readable storage medium, and when executed by a processor, the computer program implements the steps of the hardware control method described in any of the embodiments described above.

The non-transitory readable storage medium may include various non-transitory readable storage media capable of store program codes, such as a USB flash drive, a removable hard disk, a read-only memory (ROM), a random access memory (RAM), a magnetic disk, or an optical disk. A computer program is stored on the non-transitory readable storage medium, and when executed by a processor, the computer program implements the following steps: acquiring a chip selection signal and an operation signal generated based on operation information; determining a target output port from all output ports of a gating module according to the chip selection signal; and transmitting the operation signal to a corresponding flash load via the target output port, so that the flash load responds to the operation signal based on the chip selection signal.

In the present embodiment, a plurality of output ports of the gating module in a hardware control system are connected with a plurality of flash loads in a one-to-one correspondence manner, the target output port is determined according to the chip selection signal, and the operation signal is only sent to the flash load connected with the target output port. In this way, on one hand, the number of flash loads mounted on each NAND bus is reduced, and on the other hand, point-to-point communication between a control module and the flash load is implemented, thereby improving the NAND read-write rate, indirectly optimizing product performance parameters of the SSD, and improving the competitiveness of the SSD.

In an embodiment, when executed by the processor, a computer sub-program stored in the non-transitory readable storage medium may implement the following steps: acquiring the chip selection signal that is generated based on the operation information and corresponds to each execution unit; determining an input gating signal based on all chip selection signals; and determining the target output port from the plurality of output ports according to the input gating signal.

In an embodiment, when executed by the processor, the computer sub-program stored in the non-transitory readable storage medium may implement the following steps: receiving a preset correspondence between the chip selection signals and the output ports; and determining the target output port according to the input gating signal and the correspondence.

In an embodiment, when executed by the processor, the computer sub-program stored in the non-transitory readable storage medium may implement the following step: upon receiving first configuration information, configuring the chip selection signal received by the gating module as an input signal.

In an embodiment, when executed by the processor, the computer sub-program stored in the non-transitory readable storage medium may implement the following step: upon receiving second configuration information, configuring the functions of the gating module.

In an embodiment, when executed by the processor, the computer sub-program stored in the non-transitory readable storage medium may implement the following steps: determining whether there is a valid chip selection signal in the chip selection signals received by each first port; in a case that there is the valid chip selection signal in the chip selection signals received by each first port, determining a valid input gating signal based on the valid chip selection signal; and determining the target output port from the plurality of output ports according to the valid input gating signal.

It should also be noted that, in the present specification, relational terms, such as first and second, are merely used for distinguishing one entity or operation from another entity or operation, and do not necessarily require or imply that any such actual relationship or order exists between these entities or operations. Moreover, the terms “include”, “contain” or any other variants thereof are intended to cover non-exclusive inclusions, such that a process, a method, an article or a device including a series of elements not only includes those elements, but also includes other elements that are not explicitly listed, or also includes elements inherent to such a process, method, article or device. In the case that there are no more restrictions, the element defined by the sentence “including a . . . ” does not exclude the existence of other identical elements in the process, the method, the article or the device that includes the element.

The above description of the disclosed embodiments enables those skilled in the art to implement or use the present disclosure. Various modifications to the embodiments will be apparent to those skilled in the art, and the general principles defined herein may be implemented in other optional embodiments without departing from the spirit or scope of the present disclosure. Thus, the present disclosure will not be limited to the embodiments shown herein, but is intended to conform to the widest scope consistent with the principles and novel features disclosed herein.

1. A hard disk control system, comprising:
a control module, configured to receive operation information, and generate an operation signal and a chip selection signal according to the operation information; and
at least one gating module, wherein each gating module comprises a plurality of output ports, the plurality of output ports are connected with a plurality of flash loads in a one-to-one correspondence manner, and each gating module is configured to determine a target output port from the plurality of output ports according to the chip selection signal, and transmit the operation signal to the corresponding flash load via the target output port, so that the flash load responds to the operation signal based on the chip selection signal.

2. The hard disk control system according to claim 1, wherein each flash load comprises a plurality of execution units; and
each flash load is configured to select any execution unit according to the chip selection signal to serve as an execution unit for responding to the operation signal.

3. The hard disk control system according to claim 2, wherein each flash load and the control module are further configured to:
send a channel connection of the chip selection signal;
receive the chip selection signal output by the control module via a channel, so as to select any execution unit according to the chip selection signal to serve as the execution unit for responding to the operation signal, wherein the chip selection signal is valid at a target level.

4. The hard disk control system according to claim 1, wherein each flash load comprises a plurality of execution units, and the gating module is configured to:
acquire the chip selection signal corresponding to each execution unit;
determine an input gating signal based on all chip selection signals; and
determine the target output port from the plurality of output ports according to the input gating signal, and the transmit the operation signal to the corresponding flash load via the target output port.

5. The hard disk control system according to claim 4, wherein the gating module is further configured to receive a preset correspondence between the chip selection signals and the output ports; and
the process of determining the target output port from the plurality of output ports according to the input gating signal comprises:
determining the target output port according to the input gating signal and the correspondence.

6. The hard disk control system according to claim 1, wherein each flash load comprises a plurality of execution units, the gating module comprises a logical processing unit and a switch control unit, the switch control unit comprises a first port and a plurality of second ports, the first port of the switch control unit is configured to acquire the operation signal generated by the control module, and the second ports serve as the output ports of the gating module; and
the logical processing unit is configured to acquire the chip selection signal corresponding to each execution unit, determine the input gating signal based on all chip selection signals, determine the target output port from the plurality of output ports according to the input gating signal, and control the target output port to communicate with the first port of the switch control unit, so as to transmit the operation signal acquired by the first port of the switch control unit to the flash load connected with the target output port.

7. The hard disk control system according to claim 1, wherein the hard disk control system further comprises:
a first configuration module, connected with a first configuration end of the gating module, and configured to configure the chip selection signal received by the gating module as an input signal.

8. The hard disk control system according to claim 7, wherein the first configuration module comprises a first resistor, a first end of the first resistor is connected with a power supply module, and a second end of the first resistor is connected with the first configuration end.

9. The hard disk control system according to claim 1, wherein the hard disk control system further comprises:
a second configuration module, connected with a second configuration end of the gating module, and configured to configure the functions of the gating module.

10. The hard disk control system according to claim 9, wherein the second configuration module comprises a second resistor and a third resistor, a first end of the second resistor is connected with the power supply module, a second end of the second resistor and a first end of the third resistor are both connected with the second configuration end, and a second end of the third resistor is grounded.

11. The hard disk control system according to claim 1, wherein the hard disk control system further comprises:
a third configuration module, connected with a third configuration end of the gating module, and configured to enable a transmission channel of the gating module.

12. The hard disk control system according to claim 1, wherein the gating module is a high-speed bus switch.

13. The hard disk control system according to claim 1, wherein the control module comprises a PCIe 3.0 controller.

14. The hard disk control system according to claim 1, wherein the operation signal comprises a read operation signal or a write operation signal or an erase operation signal.

15. The hard disk control system according to claim 1, wherein the gating module comprises a plurality of first ports, each first port of the gating module is configured to receive at least one chip selection signal, and the gating module is configured to:
determine whether there is a valid chip selection signal in the chip selection signals received by each first port;
in a case that there is the valid chip selection signal in the chip selection signals received by each first port, determine a valid input gating signal based on the valid chip selection signal; and
determine the target output port from the plurality of output ports according to the valid input gating signal, and transmit the operation signal to the corresponding flash load via the target output port, so that the flash load responds to the operation signal based on the chip selection signal.

16. A storage system, comprising the hard disk control system according to claim 1.

17. A server system, comprising the hard disk control system according to claim 1.

18. A hard disk control method, applied to the hard disk control system according to claim 1, wherein the hard disk control method comprises:
acquiring a chip selection signal and an operation signal generated based on operation information;
determining a target output port from all output ports of a gating module according to the chip selection signal; and
transmitting the operation signal to a corresponding flash load via the target output port, so that the flash load responds to the operation signal based on the chip selection signal.

19. An electronic device, comprising:
a memory, configured to store a computer program; and
a processor, configured to execute the computer program to implement the steps of the hard disk control method according to claim 18.

20. A non-transitory readable storage medium, wherein a computer program is stored on the non-transitory readable storage medium, and when executed by a processor, the computer program implements the following operations:
acquiring a chip selection signal and an operation signal generated based on operation information;
determining a target output port from all output ports of a gating module according to the chip selection signal; and
transmitting the operation signal to a corresponding flash load via the target output port, so that the flash load responds to the operation signal based on the chip selection signal.
